(19) United States
(12) Patent Application Publication
(10) Pub. No.: US 2011/0133597 A1
(43) Pub. Date: Jun. 9, 2011

(54) ELECTROMECHANICAL SYSTEMS, WAVEGUIDES AND METHODS OF PRODUCTION

(75) Inventors: Andrei J. Pavlov, Naantali (FI); Yelena V. Pavlova, Naantali (FI)

(73) Assignee: ScanNanoTek Oy, Turku (FI)

(21) Appl. No.: 12/961,079

(22) Filed: Dec. 6, 2010

Related U.S. Application Data
(60) Provisional application No. 61/267,027, filed on Dec. 5, 2009.

(51) Int. Cl. H02N 11/00; H01P 3/00; H05K 13/00

(52) U.S. Cl. 310/300; 333/236; 29/592.1

(57) ABSTRACT

A method of producing an electromechanical device includes forming a layer of density-changing material on a substructure, and forming a support layer on at least a portion of the layer of density-changing material. The density-changing material has a first density during the forming the layer and a second density subsequent to the forming the support layer, the second density being greater than the first density such that the layer of density-changing material shrinks in at least one dimension to provide a gap between the layer of density changing material and at least one of the support layer and the substructure. A combined electronic and electromechanical device has a substrate, an electronic circuit formed on the substrate, and an electromechanical system formed on the substrate to provide a combined electronic and electromechanical device on a common substrate. The electromechanical system comprises a structure that is free to move within a gap defined by the electromechanical system.

### CROSS-REFERENCE OF RELATED APPLICATION

This application claims priority to U.S. Provisional Application No. 61/267,027 filed Dec. 5, 2009, the entire contents of which are hereby incorporated by reference.

### BACKGROUND

1. Field of Invention

The current claims relate to electromechanical systems and waveguides, devices that incorporate the electromechanical systems and waveguides, and methods of production.

2. Discussion of Related Art

Microelectromechanical systems (MEMS) devices comprise microstructures that are usually separated from other control elements, for example control electrodes, by narrow air gaps. The MEMS devices have movable structures that can move over the space provided by the gap. Usually, this movement is used to make a contact with an electrode, such as in a MEMS switch. Variation of the width of the gap can be used to change electrical characteristics of the device, such as a variable capacitor. In many applications, the MEMS structure is used as a sensitive element and the movement of the microstructure is used to detect an external effect such as pressure, acceleration, etc. In many applications, performance of the MEMS structure is limited by the size of the gap. Larger gaps require greater forces to enable the MEMS structure to move. Accordingly, the sensitivity of the MEMS structure is lower for larger gaps and higher power is needed to control it. For example, electrical voltages that are needed for the operation of MEMS devices is relatively high, i.e., of the order of a few tens of Volts. To improve performance of MEMS devices, significantly smaller gaps are needed. The smaller gaps can improve sensitivity and allow for lower power operation of the devices. Most traditional MEMS devices require a vacuum in the gap and, therefore, require special protection from ambient atmosphere, such as sealing and encapsulation.

MEMS structures are usually produced using a layer referred as a sacrificial layer because it is removed during fabrication. The sacrificial layer is prepared in the space which later becomes a gap which separates the movable component of the MEMS structure from other parts of the device, for example, control electrodes. The sacrificial layer is temporarily included in the device to enable preparation of the movable component of the MEMS structure on top of it. After that, the sacrificial layer is removed by etching to provide the gap that separates the movable component of the MEMS structure and the electrodes. The use of the sacrificial layer and etching process limits the minimum size of the gap because it is more difficult to etch thinner sacrificial layer materials underneath the top structure. To improve etching processes one can make holes in the movable component of the MEMS structure. However, the smallest gaps obtained by this approach are in the range from 1 to 1.5 micrometers. In addition, the etching process is incompatible with the production of many electronic circuits on the same substrate, such as CMOS integrated circuits. Therefore, there remains a need for improved electromechanical systems, methods of producing electromechanical systems and devices that incorporate the electromechanical systems.

### SUMMARY

A method of producing an electromechanical device according to an embodiment of the current invention includes forming a layer of density-changing material on a substructure, and forming a support layer on at least a portion of the layer of density-changing material. The density-changing material has a first density during the forming the layer and a second density subsequent to the forming the support layer, the second density being greater than the first density such that the layer of density-changing material shrinks in at least one dimension to provide a gap between the layer of density changing material and at least one of the support layer and the substructure.

A combined electronic and electromechanical device according to an embodiment of the current invention has a substrate, an electronic circuit formed on the substrate, and an electromechanical system formed on the substrate to provide a combined electronic and electromechanical device on a common substrate. The electromechanical system comprises a structure that is free to move within a gap defined by the electromechanical system.

An electromechanical system according to an embodiment of the current invention has a substructure, and a movable component attached to the substructure such that a gap is provided between the movable component and the substructure. The gap is less than about 500 nm.

An apparatus according to an embodiment of the current invention has an electromechanical system that has a substructure, and a movable component attached to the substructure such that a gap is provided between the movable component and the substructure. The gap is less than about 500 nm.

A method of producing a waveguide according to an embodiment of the current invention includes providing a substructure, forming a layer of density-changing material on the substructure, and forming an upper layer on at least a portion of the layer of density-changing material. The density-changing material has a first density during the forming the layer and a second density subsequent to the forming the upper layer, the second density being greater than the first density such that the layer of density-changing material shrinks in at least one dimension to provide a gap between the layer of density changing material and at least one of the upper layer and the substructure.

### BRIEF DESCRIPTION OF THE DRAWINGS

Further objectives and advantages will become apparent from a consideration of the description, drawings, and examples.

FIG. 1 is a schematic illustration of the production of an electromechanical device according to an embodiment of the current invention.

FIG. 2 is a schematic illustration of the production of an electromechanical device according to another embodiment of the current invention.

FIG. 3 is a schematic illustration of the production of an electromechanical device according to another embodiment of the current invention.

FIG. 4 is a schematic illustration of the production of an electromechanical device according to another embodiment of the current invention.

FIG. 5 is a schematic illustration of the production of an electromechanical device according to another embodiment of the current invention.

FIG. 6 is a schematic illustration of an electromechanical device according to another embodiment of the current invention.

FIG. 7 is a schematic illustration of an electromechanical device according to another embodiment of the current invention.

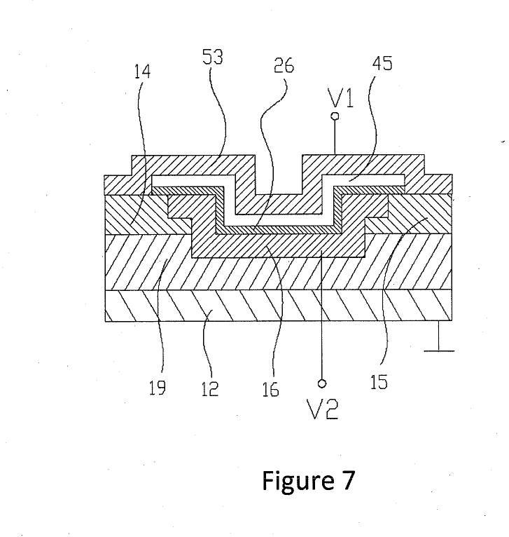

FIG. 8 is a schematic illustration of an electromechanical device according to another embodiment of the current invention.

FIG. 9 is a schematic illustration of an electromechanical device according to another embodiment of the current invention.

FIG. 10 is a schematic illustration of an electromechanical device according to another embodiment of the current invention.

FIG. 11 is a schematic illustration of an electromechanical device according to another embodiment of the current invention.

FIG. 12 is a schematic illustration of an electromechanical device according to another embodiment of the current invention.

FIG. 13 is a schematic illustration of an electromechanical device according to another embodiment of the current invention.

FIG. 14 is a schematic illustration of an electromechanical device according to another embodiment of the current invention.

FIG. 15 is a schematic illustration of an electromechanical device according to another embodiment of the current invention.

FIG. 16 is a schematic illustration of an electromechanical device according to another embodiment of the current invention.

FIG. 17 shows an example of a microchip that include both an electronic integrated circuit as well as MEMS devices fabricated on the same substrate.

### DETAILED DESCRIPTION

Some embodiments of the current invention are discussed in detail below. In describing embodiments, specific terminology is employed for the sake of clarity. However, the invention is not intended to be limited to the specific terminology so selected. A person skilled in the relevant art will recognize that other equivalent components can be employed and other methods developed without departing from the broad concepts of the current invention. All references cited anywhere in this specification are incorporated by reference as if each had been individually incorporated.

Some embodiments of the current invention are directed to Micro-electromechanical systems (MEMS) and nano-electromechanical systems (NEMS) and methods of producing the MEMS and NEMS. The MEMS and NEMS according to some embodiments of the current invention can be applied in RF applications, mobile technologies, photonics, energy, solar cells, telecommunications, transistors and diodes for example. Methods of fabricating MEMS and NEMS devices according to some embodiments of the current invention allow the fabrication of structures having nanogaps which are significantly smaller than 1 micrometer and can be as small as a few nanometers in size, or even less than 1 nm (e.g., 0.5 nm). (In the remainder of this description, we often refer to MEMS devices, but that should be interpreted as including NEMS devices.) There can be several nanogaps in one device and the device may have multigap or multi-nanogap structures, according to some embodiments of the current invention. Such structures can be used, for example, in transistors. In addition, methods of producing devices according to some embodiments of the current invention allow us to simplify fabrication of MEMS devices by avoiding encapsulation or other protection procedures such as sealing, etc. In addition, methods of production according to some embodiments of the current invention can also be used for encapsulation of devices. The fabrication methods according to some embodiments of the current invention can be used to make planar waveguides for light transmission or transmission lines for RF signals of high frequency in the GHz range. Long structures having nanogaps inside can be a new type of nanotubes. In addition, fabrication methods according to some embodiments of the current invention allow for the fabrication of vacuum gaps that do not need special sealing or protection against ambient atmosphere. For example, fabrication methods according to some embodiments of the current invention allow for fabrication of gaps inside the material and therefore, the gap automatically provides a vacuum relative to the surrounding environment.

The term vacuum as used here is intended to have a broad meaning to include partial vacuums as well as substantially complete vacuums, as long as the gas pressure within the gap is less than that of the surrounding environment. Nonetheless, in some cases, the vacuum can also be a high vacuum so that there is little easily discernable gas in the gap.

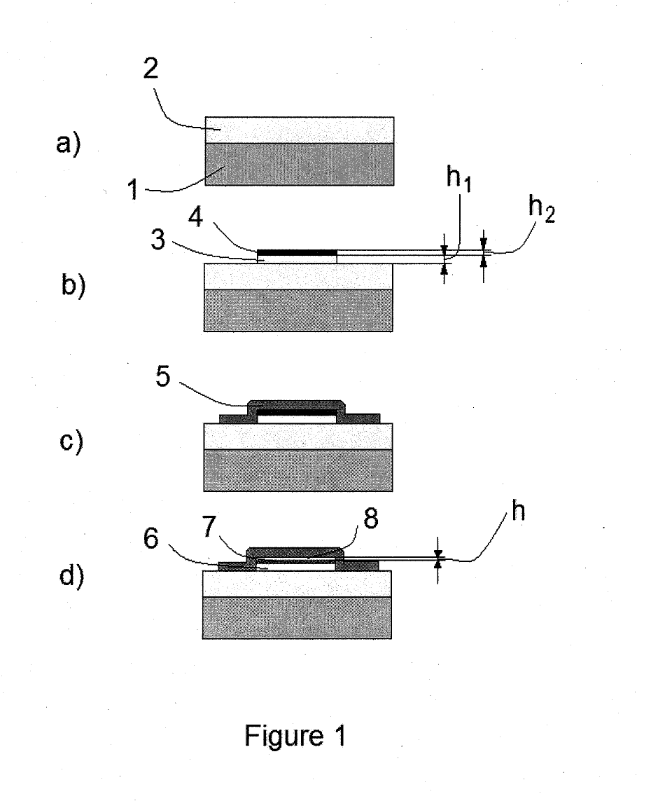

An embodiment of the current invention provides a method of fabricating ultrathin gaps that can have a size of few nanometers, for example. We call this gap a nanogap. According to some aspects of the current invention, the nanogap can be formed when two or more specially chosen materials chemically react with each other to form a final material with higher density than the initial materials. Accordingly, the higher density will result in smaller volume. If these materials are placed between two solid structures, then the chemical reaction will lead to shrinking the volume occupied by the inner material. As a result, the difference between the initial volume and the final volume will release an empty space that will form the gap. The greater the difference between the densities of initial components and the density of the final material, the larger the volume that can be released. In addition to chemical reaction, a diffusion process can take place. The fabrication of an example of a device that has a nanogap according to an embodiment of the current invention is illustrated schematically in FIG. 1.

In FIG. 1, stage a) shows a substrate 1 and an isolation layer 2 on top of it. Stage b) shows two layers, material M₁ 3 and material M₂ 4 on top of it. The bottom layer M₁ has thickness h₁ and the top layer has thickness h₂. Both materials form a structure having thickness h₁+h₂. Stage c) shows a structure 5 prepared on top of the layers 3 and 4. During stage d) materials M₁ and M₂ are reacting with each other with formation of materials M₁ₓ 6 and M₂ₓ 7. The new materials have higher density and accordingly smaller volume, releasing a gap 8 with thickness h_{g}. The thickness h_{g} can be calculated from the difference between the initial volume and final volume of the layered structure.

The effect can be estimated mathematically using the law of conservation of mass. For example, consider the case in which the initial density of the first layer is ρ₁ and its thickness is h₁, and the initial density of the second layer is ρ₂ with a thickness of h₂. After the reaction, the density of the first layer changes to ρ₁ₓ, and its thickness changes to h₁ₓ, and the density of the second layer changes to ρ₂ₓ and its thickness changes to h₂ₓ. The gap h_{g} can be obtained from the following relation

h₁+h₂=h₁ₓ+h₂ₓ+h_{g}. (1)

Using the law of conservation of mass leads to the relation

ρ₁h₁+ρ₂h₂=ρ₁ₓh₁ₓ+ρ₂ₓh₂ₓ, (2)

where one can assume that thin layers change their volumes along thickness and don't change their surface areas. One can be seen from these equations that different conditions can result in providing a gap, as follows:
1. ρ₁<ρ₁ₓ; h₁<h₁ₓ; ρ₂<ρ₂ₓ and h₂<h₂ₓ. Both layers become thinner and the gap h_{g} is a sum of two effects h=(h₁−h₁ₓ)+(h₂−h₂ₓ).
2. ρ₁<ρ₁ₓ; h₁<h₁ₓ; ρ₂>ρ₂ₓ and h₂>h₂ₓ. One layer becomes thinner, another layer thicker. However, the final result is obtained from the difference h=(h₁−h₁ₓ)−(h₂ₓ−h₂).

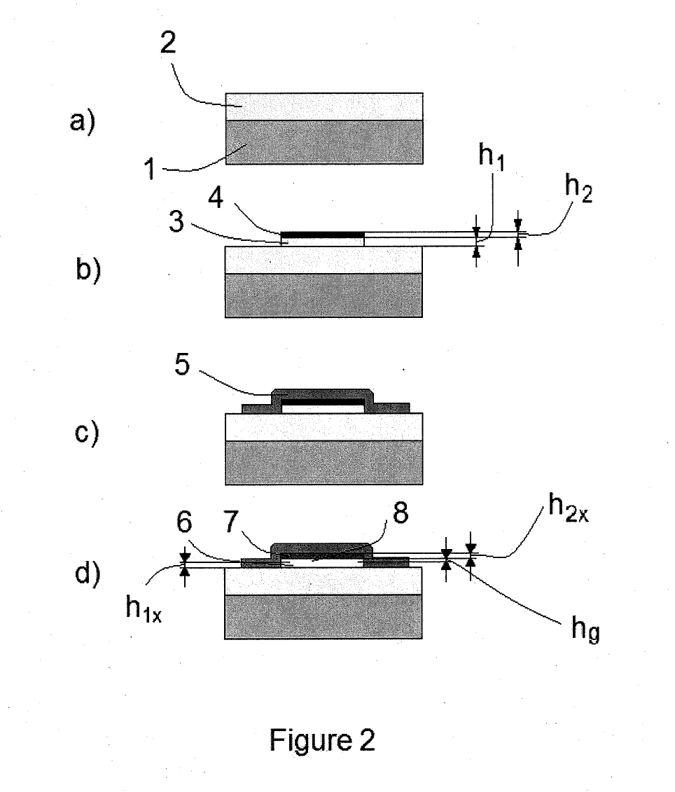

The nanogap can be formed above the layered structure during shrinking as shown in FIG. 1, or within the layered structure as shown in FIG. 2. In the FIG. 2, the top layer M₂ is fixed to the MEMS structure. This can be caused by significant adhesion between the material M₂ and material of the MEMS structure, or by chemical reaction between the MEMS material and M₂.

According to another embodiment of the current invention, there can be combinations of three or more layers. The chemical reaction can occur with three or more participating layers. Accordingly, the final effect will be obtained from similar equations. For example, for three layers

h₁+h₂+h₃=h₁ₓ+h₂ₓ+h₃ₓ+h_{g}, (3)

and from law of conservation of mass

ρ₁h₁+ρ₂h₂+ρ3h₃=ρ₁ₓh₁ₓ+ρ₂ₓh₂ₓ+ρ₃ₓh₃ₓ. (4)

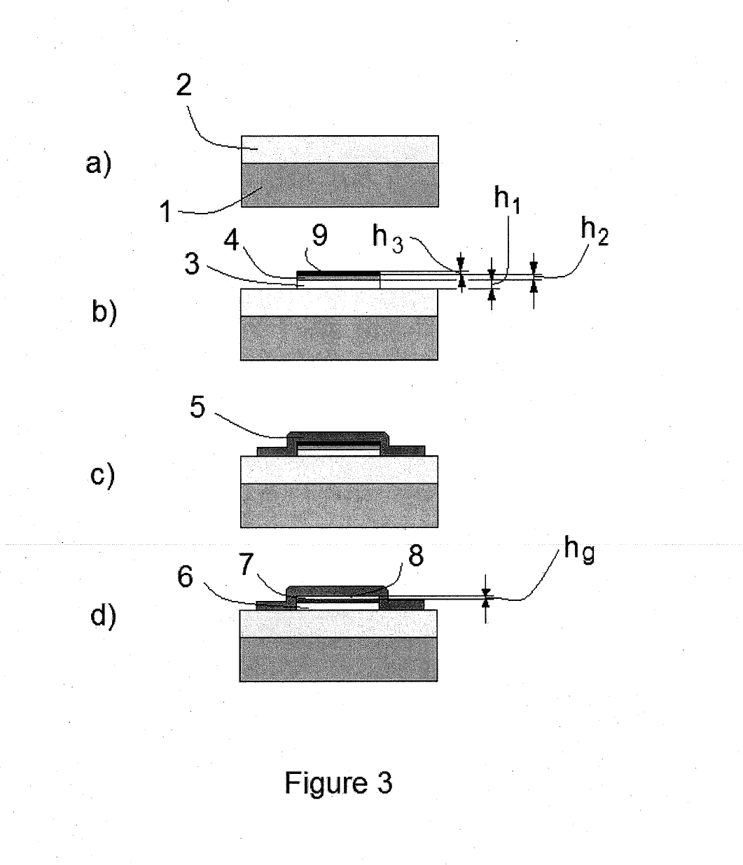

FIG. 3 shows an example where three layers M₁ 3 M₂ 4 and M₃ 9 are deposited with corresponding thicknesses h₁, h₂, and h₃. The gap h_{g} is formed during reaction of the three materials.

Similarly, one can design more complex reactions when chemical reactions take place in separate stages, for example, material M₁ can react first with material M₂ to form material M₁₂. Then material M₁₂ reacts with material M₃ resulting in material M₁₂₃ etc. Physical diffusion, temperature, radiation, incident illumination and other physical processes can be used to control the reaction.

According to further embodiments of the current invention, more complex structures can be used for the fabrication of more than one nanogap in a device. One can prepare two or more gaps in one device by methods similar to those described above. Furthermore, a single layer of material can also be used to produce structures that have a gap. For example, the single layer can undergo a phase change such that the final phase has a greater density than the initial phase. In another embodiment, the single layer could undergo sublimation such that the layer increases in density. Furthermore, phase changes and/or sublimation processes could be combined with chemical reactions in more complex layer structures in some embodiments of the current invention.

In a more general sense, a method of producing an electromechanical device according to an embodiment of the current invention includes forming a layer of density-changing material on a substructure, and forming a support layer on at least a portion of the layer of density-changing material. The density-changing material has a first density during the forming the layer and a second density subsequent to the forming the support layer, the second density being greater than the first density such that the layer of density-changing material shrinks in at least one dimension to provide a gap between the layer of density changing material and at least one of the support layer and the substructure.

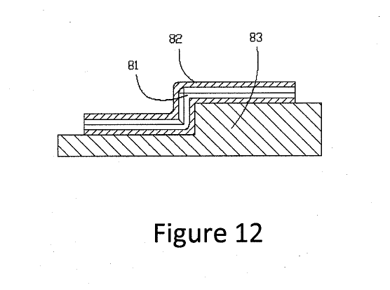

The substructure can be a substrate in some embodiments of the current invention, or can be a more complex structure. For example, the substructure in the example of FIG. 1 includes the substrate 1 and the isolation layer 2. The substructure can be more complex structures in other embodiments of the current invention. It may have, for example, a step-like structure, see FIG. 12, and the gap can be formed along the step structure. The layer of density changing material can be a layer of a single material, a layer of multiple materials or a layer that includes two or more sub-layers of materials, for example. The support layer can be any structure suitable for the particular application that attaches to at least a portion of the layer of density-changing material. In some cases the support layer can provide a portion of the structure such that the gap will provide a vacuum. In the example of FIG. 1, the structure 5 is an example of a support layer that provides, along with isolation layer 2 and layers 6 and 7, an enclosed structure such that the gap 8 will be a vacuum.

The density-changing material changes density due to a phase change in its structure in some embodiments of the current invention. In other embodiments, the density-changing material changes density due to sublimation. In further embodiments, the density changing material changes density due to one or more chemical reactions. In some embodiments, the density changing material changes density as the result of a combination of one of more of a phase change, sublimation, chemical reactions or diffusion.

In some embodiments of the current invention, the layer of density-changing material provides a membrane structure after it shrinks. In some embodiments, the membrane can be formed in a vacuum relative to a surrounding environment. In other embodiments, external components can form a membrane, such as the structure 5 in the example of FIG. 1. In some embodiments, the support layer is formed over a portion of the layer of density-changing material leaving an end of the density-changing material uncovered such that the layer of density-changing material provides a cantilever structure after it shrinks in at least one dimension.

In some embodiments, energy is transferred to the layer of density-changing material to initiate a phase change, sublimation and/or a chemical reaction. The energy transfer can include at least one of heating, passing an electrical current through the layer of density-changing material, or directing radiation onto the layer of density-changing material The radiation can be electromagnetic radiation, for example.

The forming the layer of density-changing material can include forming a plurality of sub layers of respective pluralities of materials. The general concepts of the current invention are not limited to a particular number of sub-layers of materials, which can be two, three or more than three sub-layers, for example.

In some embodiments of the current invention, the gap is less than 1 μm such that said electromechanical device is a micro-electromechanical system or nano-electromechanical system. However, the general concepts of the method of producing electromechanical devices are not limited to producing only MEMS and NEMS devices. Devices with larger gaps can also be produced according to some embodiments of the current invention. In some embodiments, the gap is less than 0.5 μm such that the electromechanical device produced is a nano-electromechanical system. In further embodiments, the gap in the NEMS devices produced is less than 1 μm and greater than 0.5 nm, and in some embodiments the gap is less than 0.5 μm and greater than 0.5 nm.

Another embodiment of the current invention is directed to an electromechanical system that has a substructure, and a movable component attached to the substructure such that a gap is provided between the movable component and the substructure. The gap is less than about 500 nm. In some embodiments, the gap is less than about 200 nm. In further embodiments, the gap is less than about 100 nm and greater than about 0.5 nm.

The movable component can be a membrane in some embodiments or cantilever (see, for example, U.S. patent application Ser. No. 12/370,882 by A. Pavlov et al., “Resonant MEMS Device that Detects Photons, Particles and Small Forces”, filed Feb. 13, 2009, the entire content of which is incorporated herein by reference) in some embodiments or a bridge-like structure in some embodiments of the current invention. The electromechanical system can include enclosing structures in some embodiments of the current invention such that the gap is substantially a vacuum relative to a surrounding environment.

Further embodiments of the current invention include an apparatus that includes one or more electromechanical systems according to the current invention. Another embodiment of the current invention is directed to a method of producing a waveguide that includes providing a substructure; forming a layer of density-changing material on the substructure; and forming an upper layer on at least a portion of the layer of density-changing material. The density-changing material has a first density during the forming the layer and a second density subsequent to the forming the upper layer, the second density being greater than the first density such that the layer of density-changing material shrinks in at least one dimension to provide a gap between the layer of density changing material and at least one of the upper layer and the substructure.

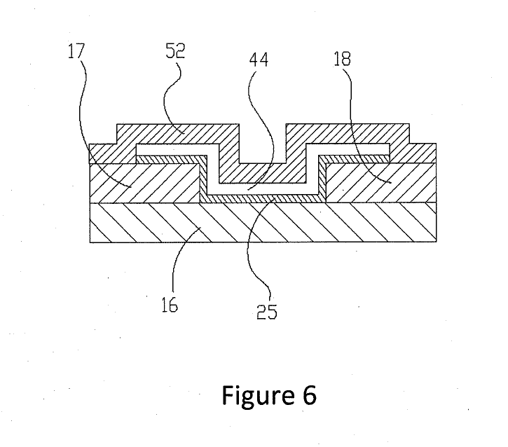

An example of a device based on the fabrication method according to an embodiment of the current invention is shown in FIG. 6. Here the nanogap is prepared on the step structure showing the possibility for different device design. The step structure is formed from a substrate 16, second layer 17, 18 forming the step structure, density-changing layer 25, top structure 52 and the nanogap 44. The top structure 25 can have a step profile as well. For example, if the device is prepared by a CMOS process where the layer has a near-uniform thickness, for example, when the deposition is made using physical vapor deposition, magnetron sputtering, chemical vapor deposition and others, then the layer will form the profile correlated to that of structures underneath.

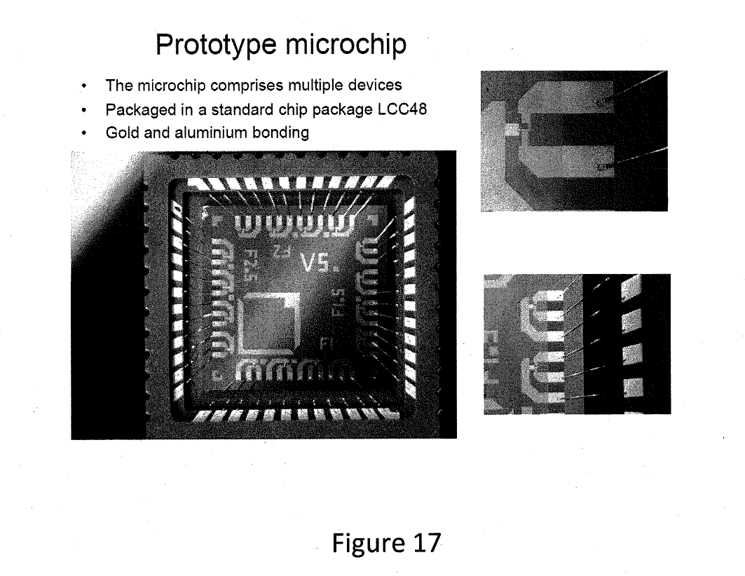

FIG. 17 shows a device, i.e., variable capacitor or varactor, according to an embodiment of the current invention. The device comprises a substrate 12, resistive layer 19, next resistive layer 14,15; bottom electrode 16, density-changing layer 26, top MEMS structure 53 and nanogap 45. The nanogap's size may vary, for example, from 1 nm to 100 nm. The device is a two-terminal device and electrical connection is made between the bottom electrode 16 and the top structure 53. Small gaps allow one to make smaller sized devices yet with sufficiently large capacitance values. The capacitance is varied by applying voltage to the device resulting in variation of the gap size. A smaller gap results in increase of the capacitance value. The geometry of the device can be simpler if the layer 14,15 is skipped from the design. Electrical connection to the bottom electrode can be made using a side electrode connection going in the isolation layer, or using a via which is a standard/common solution for connection.

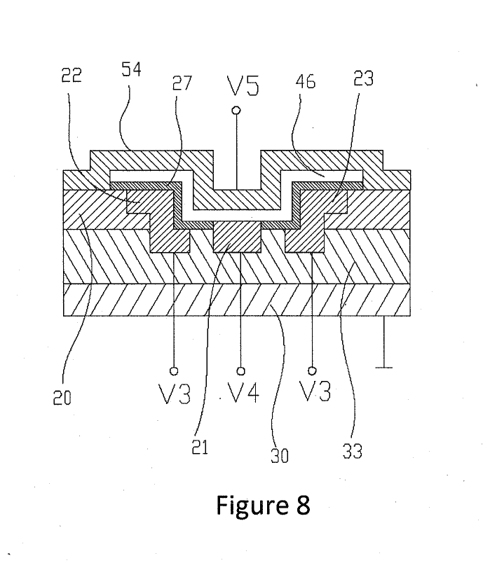

FIG. 8 shows a switch device that can be used in RF applications according to an embodiment of the current invention. The device comprises a substrate 30, resistive layer 33, another resistive layer 20 forming step structures, electrodes 21,22 and 23; density-changing layer 27, top MEMS structure 54 and nanogap 46. The electrode 21 is used for switching. Its top surface is slightly closer to the MEMS structure than those of other electrodes. Switching is performed between the MEMS structure 54 and the electrode 21 forming an Ohmic contact with low resistance. Other electrodes 22, 23 can geometrically surround the electrode 21 and electrically the electrodes 22 and 23 can be connected to each other. These electrodes are used for actuation of the device. When an electrical voltage is applied to the electrodes 22, 23 the MEMS structure moves closer to the electrode 21, and at a certain voltage switching is performed between 54 and 21. The electrodes 22,23 are placed at lager distance from the MEMS structure than the electrode 21 to avoid leakage current at switching. The top MEMS structure may be a membrane, bridge-like structure or cantilever. Variations in geometry of the top MEMS structure allow different geometries of the structures underneath. The step structure can be avoided or skipped in some designs so then the device may have a simpler geometry. Connection to bottom electrodes can be performed by using side electrodes going underneath in the isolation layer, or using vias.

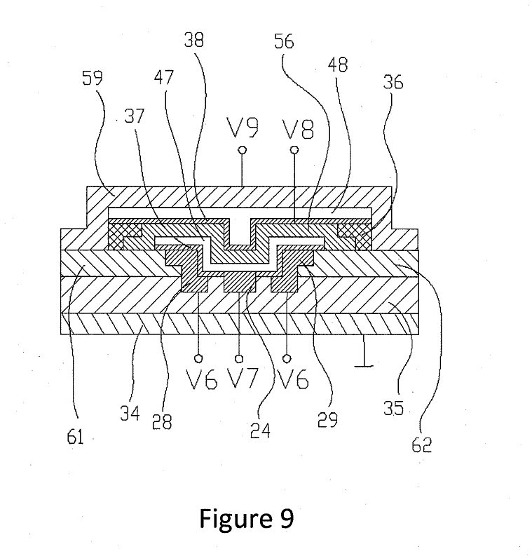

FIG. 9 shows a device with two gaps according to an embodiment of the current invention. This additional gap may have different functions. It can, for example, isolate the operating MEMS structure from the environment, or, it can separate different electrodes in more complex designs. The device of FIG. 9 comprises a substrate 34, isolation layer 35, another isolation layer 61,62 forming step structure, bottom electrodes 24,28,29; density-changing layer 37, MEMS structure 56, another density-changing layer 38, top layer 59 and two gaps 47 and 48. The device can work as a switch. The gap 48 is used to isolate the MEMS structure from influence of external forces like air pressure. This design allows different geometries of the MEMS structure 56 and bottom electrodes. The MEMS structure 56 can be a membrane, bridge, comb structure or a cantilever. Bridge- and cantilever designs allow connection between the gaps so that the MEMS structure 56 can be surrounded by a vacuum. The electrodes 28 and 29 can be connected to each another.

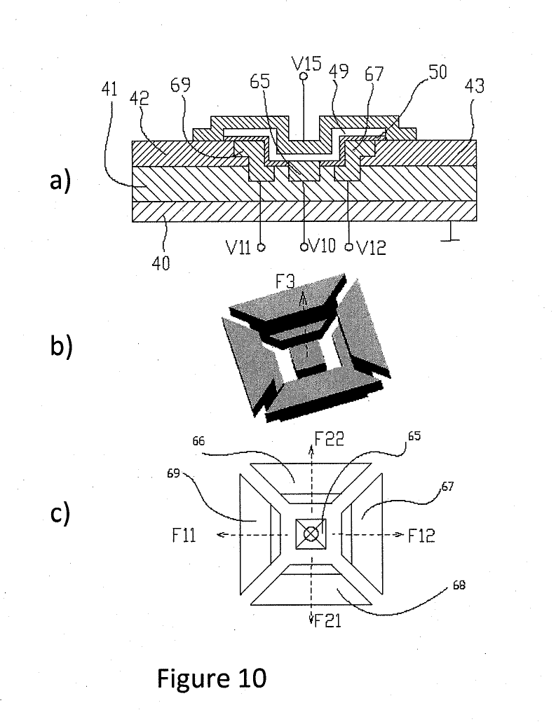

FIG. 10a shows a device that can work as an accelerometer according to an embodiment of the current invention. The device comprises a substrate 40, isolation layer 41, another isolation layer 42, 43 forming step structure; electrodes 65, 66, 67, 68 and 69; density-changing layer 50, nanogap 49 and a top MEMS structure. In this device electrodes are separated from each other and can sense motion of the MEMS structure in different direction sensing forces F11,F12, F21,F22 and F3 shown in FIG. 10c. In this device the MEMS structure can move not only vertically but also in a horizontal plane so that distances to different contacts can be changed. FIG. 10b shows schematically the electrodes. They are separated from each other. Other designs and shapes of the electrodes can be also used.

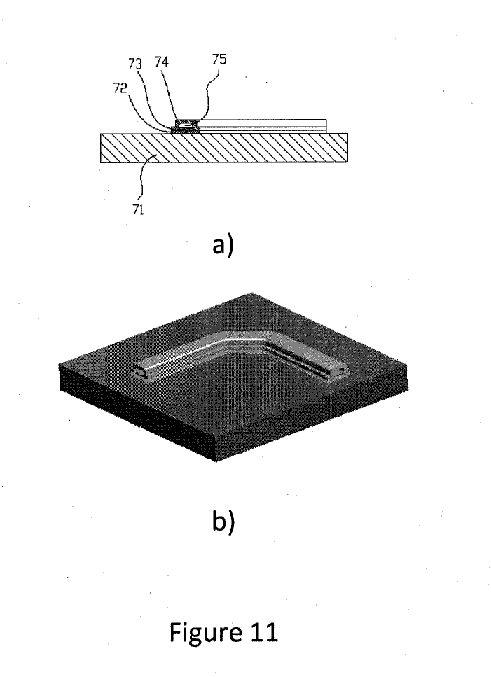

The term “waveguide” is considered in a broad sense to mean that the device can transfer electro-magnetic waves, light, radiation or electrical charge depending on materials forming the waveguide. For transferring light or radiation it is an optical waveguide. For transferring electrical charge it is a nanotube. Accordingly, materials for the device will vary depending on the application. Prior art optical waveguides use photonic crystal fibers or hollow fibers. The prior art fibers cannot be integrated on a chip with other devices like laser diodes and photodetectors and they are limited by a few materials that can be used in the process. We disclose a waveguide device that can be made of different materials, the inner gap can be very small, of the nanometer size, and the size can be predicted with a very good accuracy. An example of a waveguide device according to an embodiment of the current invention is shown in FIG. 11. The device is made on a substrate 71 and comprises a first layer 72, density-changing layer 73, top structure 74 and a gap 75. The waveguide can have a wide range of geometries that can be realized by lithography. This waveguide can be integrated with other devices on the same chip according to some embodiments of the current invention. One can consider the waveguide as an on-chip waveguide. FIG. 11b shows a perspective view of the waveguide. Depending on the wavelength, one can use different materials for the structure including semiconductor materials. The inner gap of the waveguide can be filled with a gas or liquid to obtain suitable optical characteristics.

FIG. 12 shows a waveguide that is prepared on a step-like structure. The device is prepared on a substrate 83 and comprises the structure 82 and a gap 81 that goes along the step structure. This picture demonstrates a possibility to design 3D waveguides on a chip according to some embodiments of the current invention.

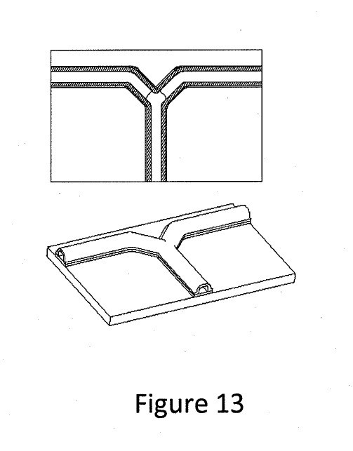

FIG. 13 shows a waveguide that splits into several branches. This picture shows that this waveguide can be used in advanced designs including optical switching matrixes, logical devices and others.

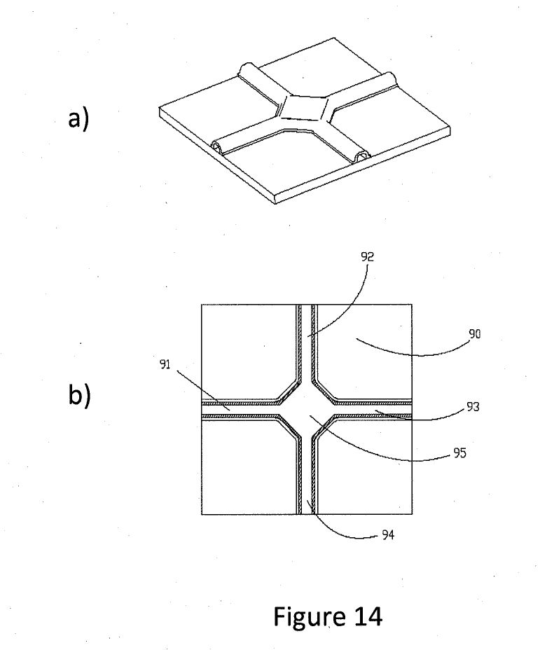

FIG. 14 shows a waveguide device according to an embodiment of the current invention that comprises a substrate 90 and four waveguides 91, 92, 93 and 94. The waveguides are connected to cavity 95. This basic structure can be used for connecting different waveguides.

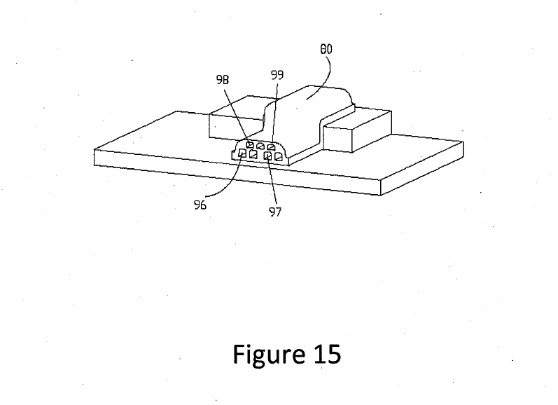

FIG. 15 shows a waveguide 80 according to an embodiment of the current invention with a multi-gap structure inside 96, 97, 98, 99 etc. Also, the device goes through a step structure.

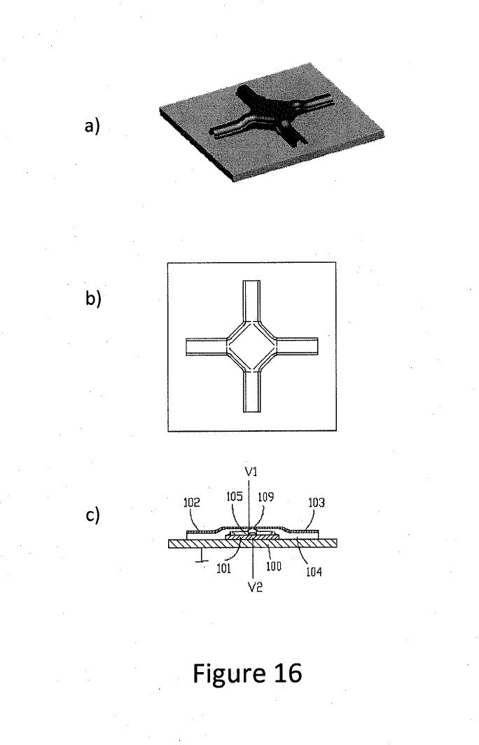

FIG. 16 shows a device where a MEMS device and waveguides are connected together according to an embodiment of the current invention. The combined structure can be used in a switching matrix, for tuning signals, logical circuits, resonators and other devices. FIG. 16a shows a general view of the device. FIG. 16b shows four waveguides connected to the MEMS device. FIG. 16c shows a MEMS device and fractions of the waveguides 102 and 103. The device comprises a substrate 100, bottom electrode 101, top electrode 109 and gaps 104 inside the waveguides and 105 in the MEMS device. The MEMS device can be actuated, for example, electrically. The waveguides can be used for transferring signals. The MEMS device can sense signals going through the waveguides and can modulate the signals. Waveguides and the MEMS device can be made of different materials. Materials for the optical waveguides can be chosen from resistive or semiconductor ones providing electrical isolation. The MEMS device may have a more complex design based on the fabrication method and devices according to some embodiments of the current invention. The geometry of the waveguide, including geometry of the gap, can change along the device. For some applications, different parts of the waveguide can be made of different materials including semiconductors. This allows one to design devices not only vertically but also horizontally.

### EXAMPLES

One can estimate the effect, for example, for aluminum (Al). It has a density of 2.7 g/cm³. When Al reacts with oxygen, the oxide Al₂O₃ will have a density of 3.96 g/cm³. If one deposits a thin layer of Al on a substrate, then oxidation will result in decreasing its thickness because the density of the oxide is greater than that of Al and the thickness of the oxide will be accordingly smaller. The relation can be obtained, taking into account that the total mass of the layer remains almost the same, i.e. if the initial thickness of the layer is h₁, initial density ρ₁, thickness after oxidation h₁ₓ and final density ρ₁ₓ, then h₁ₓ=h₁ ρ₁/ρ₁ₓ. The thickness of Al₂O₃ will be thinner by a ratio of 2.7/3.96=0.68, or 68% of the initial thickness. If, for example, the initial thickness is 10 nm, then the final thickness will be about 7 nm. When the initial layer is placed between two fixed plates, such shrinking of the layer will release a gap of about 3 nm. If the layer is prepared inside (surrounded by or enveloped by) the other material, the gap will be substantially a vacuum with respect to the surrounding environment formed inside the structure.

### Reaction Time

The formation of the nanogap according to some embodiments of the current invention depends on reaction time within the layered structure. There are three main cases:
1. Reaction time is long. This time is sufficiently longer than the time required for preparing the MEMS structure on top of it. This is the case when one wants to utilize the maximum effect from density increase. This case also can be used to make larger gaps.
2. Reaction time is short. The layers react before the MEMS structure is deposited. To slow down the reaction time one can use a buffer layer between the reacting layers to create time delay of the beginning of the reaction. For example, in FIG. 3 the material M₂ 4 can be the buffer layer. It allows reacting atoms of the material M₃ 9 to reach the layer M₁ 3. For example, when reaction occurs in layer M₁ 3 with oxygen atoms coming from the layer M₃ 9, the delay time is determined by the time needed for oxygen atoms/ions to cross the layer M₂ 4. The material for the buffer layer lets atoms travel through the buffer layer without reacting with the atoms. For example, in a reaction with oxygen the buffer layer can be a material that does not react with oxygen. The buffer layer can be made of carbon C, inert metals like Pt, Mo, Wo, Mg with Pt, nonmetals, polymers etc.
3. Reaction time is moderate. There can be applications when the reaction time of the layered structure can be of the same order as the time for fabrication of the MEMS structure. This is the case when one wants to use only part of the effect for obtaining smaller gaps.

Electronegativity of the materials can be chosen for particular applications. The buffer layer can also be used for the transfer of charge and electrons according to some embodiments of the current invention. The thickness of the buffer layer can change too in some embodiments of the current invention.

### Materials

Below are some combinations of materials that can be used for some applications of some embodiments of the current invention. However, the general concepts of the current invention are not limited to only these examples.

Metals, oxides and modifications:

| Material | density, g/cm³ |
|---|---|
| Al | 2.7 |
| Al₂O₃ | 3.96 |
| Al₂SiO₅ | 3.25 |

Some embodiments of the current invention can utilize the following regularities: formation of oxides of light metals such as sodium Na, potassium K, calcium Ca, lithium Li, magnesium Ma, beryllium Be, and others will result in an increase of the density; on the other hand, formation of oxides of heavy metals results in a decrease of the density.

Almost all inter-oxide compounds form with a decrease in density. However, increases of density can be obtained in phase transitions in metals. For example, ordinary white tin alpha-Sn has a density of 5.85 g/cm³. It transforms to gray-tin β-Sn at temperature minus 20° C. The β-Sn has a density of 7.29 g/cm³.

Increases of density can be obtained in phase transitions in oxides. For example, TiO₂ anataz has density of 3.8 g/cm³, but TiO₂ rutile has density of 4.2-4.3 g/cm³. One can add a small fraction of another material such as niobium Nb or tantalum Ta to control the electrical conductivity.

Other examples include, but are not limited to,

α-Ga₂O₃(5.88 g/cm³)→β-Ga₂O₃(6.48 g/cm³);

β-GeO₂(4.70 g/cm³)→α-GeO₂(6.24 g/cm³); and

Hexagonal SiO₂(2.65 g/cm³)-Tetragonal SiO₂(3.44 g/cm³).

Density can increase in reactions that lead to a decrease of Entropy. For example, density can increase as a result of reaction of oxides of a metal having different oxidation ratios. For example, oxide of Bismuth (II) BiO having density of 7.20 g/cm³ reacts with oxide of Bismuth (V) Bi₂O₅ having a density 5.10 g/cm³ to form the oxide of Bismuth (III):

4BiO+Bi₂O₅=3Bi₂O₃.

The resultant oxide Bi₂O₃ has a density of 8.9 g/cm³. Here 4 molecules of BiO and one molecule of Bi₂O₅ form 3 molecules Bi₂O₃. The reaction leads to a decrease of molecular volume, and accordingly a decrease of Entropy.

An increase of density can be obtained by sublimation of some easily evaporating volatile oxides: OsO₄ (evaporation temperature 131° C.), Re₂O₇ (evaporating temperature 359° C.), for example.

An increase of density can be obtained during reduction of oxides of heavy metals with hydrogen:

CuO+H₂=Cu+H₂O.

Density can be significantly increased by reduction reactions of oxides of heavy metals releasing the metals. Some oxides, for example, oxides of Au, Ag, Pt and Ir metals decompose under heating to yield the metal and oxygen, such as:

Ag₂O→2Ag+½O₂(T>=200° C.)

IrO₂→Ir+O₂(T>1000° C.)

In the latter reaction, the density will increase from 3.15 g/cm³ for IrO₂ to 22.4 g/cm³ for Ir.

Oxides of Noble metals can be reduced by hydrogen too.

The reaction can be enhanced by thermal conditions, electromagnetic fields, illumination of light or radiation. One can use DC electrostatic fields or AC variable electrical fields or variable electrical fields at resonant oscillation of the MEMS structure.

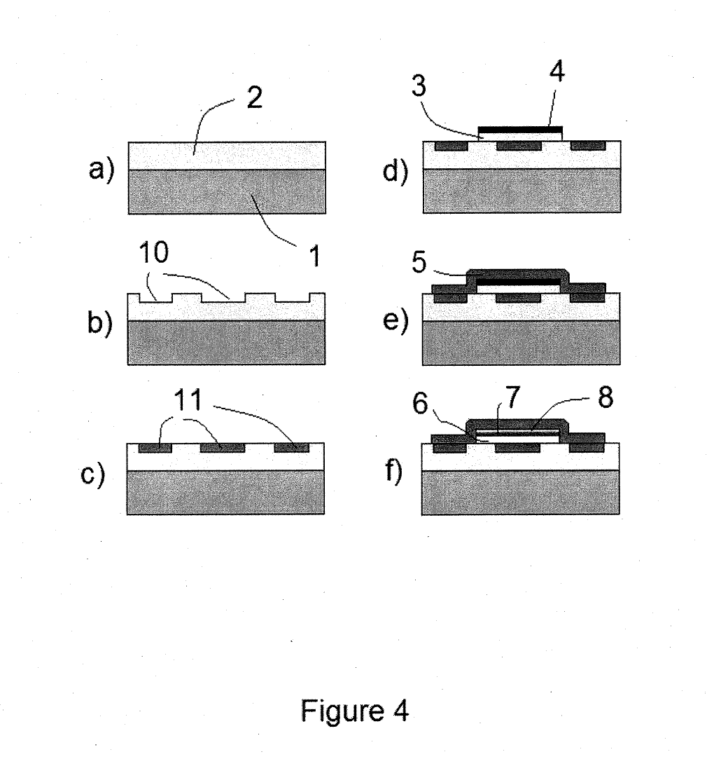

FIG. 4 shows the fabrication process of a MEMS device with electrode structures using CMOS fabrication procedures. Stage a) shows the substrate 1 and an isolation layer 2. For example, a Si wafer can be thermally oxidized to obtain the isolation layer. Stage b) shows etching of grooves for the electrodes. The proper geometry is obtained by using masks and accurate lithography. Alternatively, fine geometry can be made by direct writing, for example, by electron or optical beam. Stage c) shows deposition of electrodes in the grooves. Stage d) shows a layered structure on top of the sample. Stage e) shows the MEMS structure on top of the layered structure having contacts with side electrodes. Stage f) shows the formation of the vacuum nanogap. The nanogap is isolated from ambient atmosphere. The device shown in FIG. 4 can be used in many MEMS applications, including, but not limited to, RF MEMS switches, variable capacitors, varactors, thin film transistors, diodes and/or other tunable components, such as pressure sensors, accelerometers, detectors of a small force, including atomic force, and others. The gap can vary from a few nanometers to the micrometer range for example, depending on the application. In the extreme case, gaps of that are a fraction of a nanometer can be produced according to some embodiments of the current invention.

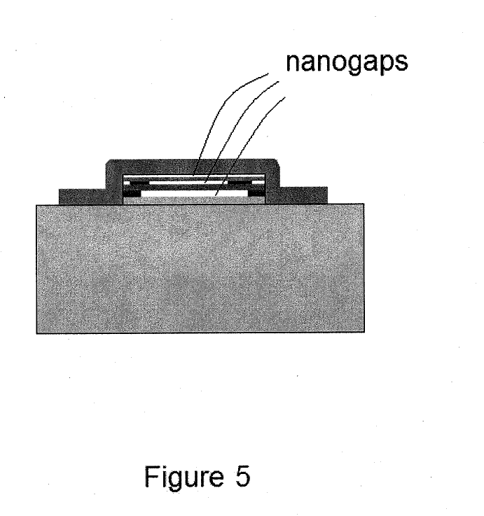

FIG. 5 shows a MEMS device with a multi-gap structure. In that particular example, there are three gaps shown, however the general concepts of the invention are not limited to a particular number of gaps.

In an embodiment of the current invention, two or more layered structures can be used for fabrication of multigaps in one device.

Below are some examples of materials that can be used for the formation of vacuum cavities using reduction of Cu from CuO.

The Copper can be reduced from its oxide. There are the following reactions:

CuO—Ti

2CuO+Ti=TiO₂+2Cu

ΔH:2*162+0−944=−620 kJ (1)
The reaction is thermodynamically beneficial and will result in emission of heat.
All initial atoms/substances will react if we use the following proportion:
2 moles of CuO and 1 mole of Ti will result in formation of 1 mole of TiO₂ and 2 moles of Cu.

| Substance | CuO | Cu | Ti | TiO₂ |
|---|---|---|---|---|
| Mass 1 mole, g | 80 | 64 | 47.8 | 80 |
| Density, g/cm³ | 6.45 | 8.96 | 4.5 | 4.2 |

One can calculate thickness h of the films per square unit needed for full reaction, i.e. initial substances will fully react, as:

hCuO=(2*80)/6.45=24.8 nm

hTi=(47.8)/4.5=10.6 nm

hTiO₂+Cu=(80)/4.2+(2*64)/8.96=19+14=33 nm
The change of the thickness is

Δh=35.4−33=2.3 nm(6.5%).

CuO—Al
The reaction of CuO and Al is the following

3CuO+2Al=Al₂O₃+3Cu (2)

ΔH:3·162+0−1676=−1190 kJ
Again, the reaction is thermodynamically advantageous and is accompanied by heat emission.
In order for all compounds/substances to have reacted completely, there should be 3 mole of CuO and 2 mole of Al, resulting in formation of 1 mole of Al₂O₃ and 2 mole of Cu.
One can calculate thicknesses of the films per square unit so that the substances have reacted completely

| Compound/substance | CuO | Cu | Al | Al₂O₃ |
|---|---|---|---|---|
| Mass 1 mole, g | 80 | 64 | 27 | 102 |
| Density, g/cm³ | 6.45 | 8.96 | 2.7 | 3.96 |

hNiO=(3·80)/6.45=37.2 nm

hAl=(2·27)/2.7=20 nm

hAl₂O₃+Cu=(102)/3.96+(3·64)/8.96=26+21=47 nm

Δh=57−46=11 nm(19%).
Reduction of the thickness is 19%.

CuO—Mg
Reaction of CuO with Mg is goes in accordance with the formula

CuO+Mg=MgO+Cu (3)

ΔH:162+0−601=−439 kJ
The reaction is thermodynamically advantageous and is accompanied by heat emission.
For complete reaction, one can take 1 mole of CuO and 1 mole of Mg, resulting in 1 mole of MgO and 1 mole of Cu.

| Substance | CuO | Cu | Mg | MgO |
|---|---|---|---|---|
| Mass 1 mole, g | 80 | 64 | 24.3 | 40.3 |
| Density, g/cm³ | 6.45 | 8.96 | 1.74 | 3.58 |

For full reaction of the films per square unit thicknesses of the films are

hCuO=(80)/6.45=12 nm

hMg=(24.3)/1.74=14 nm

hMgO+Cu=(40)/3.58+(64)/8.96=11+7=18 nm

Δh=26−18=8 nm(30%).
Reduction of thickness is 30%

CuO—Ca

CuO+Ca=Cu+CaO (4)

ΔH:162+0−635=−473 kJ
The reaction is thermodynamically advantageous and is accompanied by heat emission. In order for the substances to have reacted completely, one needs to take 1 mole of CuO and 1 mole of Ca, resulting in formation of 1 mole of Cu and 1 mole of CaO.
Given the molar mass and density,

| Substance | CuO | Cu | Ca | CaO |
|---|---|---|---|---|
| Mass 1 mole, g | 80 | 64 | 40.08 | 56 |
| Density, g/cm³ | 6.45 | 8.96 | 1.54 | 3.4 |

One can calculate thicknesses of the films

hCuO=(80)/6.45=12.4 nm

hCa=(40)/1.54=26 nm

hCaO+Cu=(56)/3.4+(64)/8.96=16+7=23 nm

Δh=38−23=15 nm(40%).
So, reduction of thickness is 40%.

CuO—Ba

CuO+Ba=Cu+BaO (5)

ΔH:162+0−548=−307 kJ
The reaction is thermodynamically advantageous and is accompanied by heat emission. In order for the substances to have reacted completely one needs to take 1 mole of CuO and 1 mole of Ba, resulting in formation of 1 mole of Cu and 1 mole of BaO.
Taking into account

| Substance | CuO | Cu | Ba | BaO |
|---|---|---|---|---|
| Mass 1 mole, g | 80 | 64 | 137.3 | 153.3 |
| Density, g/cm³ | 6.45 | 8.96 | 3.76 | 5.72 |

One can calculate the thicknesses

hCuO=(80)/6.45=12 nm

hBa=(137.3)/3.76=37 nm

hCu+BaO=(64)/8.96+153/5.72=7+27=34 nm

Δh=49−34=15 nm(30%).
Reduction of the thickness is 30%.

CuO—Be

CuO+Be=Cu+BeO (6)

ΔH:162+0−609=−447 kJ
The reaction is thermodynamically advantageous and is accompanied by heat emission.
In order for the substances to have reacted completely one needs to take 1 mole of CuO and 1 mole of Be, resulting in formation of 1 mole of Cu and 1 mole of BeO.
Taking into account

| Substance | CuO | Cu | Be | BeO |
|---|---|---|---|---|
| Mass 1 mole, g | 80 | 64 | 9 | 25 |
| Density, g/cm³ | 6.45 | 8.96 | 1.85 | 3.01 |

One can calculate the thicknesses

hCuO=(80)/6.45=12.4 nm

hBe=(9)/1.85=5 nm

hCu+BeO=(64)/8.96+25/3.01=7+8=15 nm

Δh=17−15=2 nm(12%).
Reduction of the thickness is 12%.

CuO—Zr

2CuO+Zr=2Cu+ZrO₂ (7)

ΔH:2·162+0−1100=−776 kJ
The reaction is thermodynamically advantageous and is accompanied by heat emission.
In order for the substances to have reacted completely one needs to take 2 mole of CuO and 1 mole of Zr, resulting in formation of 1 mole of Cu and 1 mole of ZrO₂.
Taking into account

| Substance | CuO | Cu | Zr | ZrO₂ |
|---|---|---|---|---|
| Mass 1 mole, g | 80 | 64 | 91.2 | 107.2 |
| Density, g/cm³ | 6.45 | 8.96 | 6.45 | 5.86 |

One can calculate

hCuO=(2.80)/6.45=25 nm

hZr=(91.2)/6.45=14 nm

hCu+ZrO₂=(2.64)/8.84+107.2/5.86=14+16=30 nm

Δh=39−30=9 nm(24%).
Reduction of thickness is 24%.

CuO—V

3CuO+2V=3Cu+V₂O₃ (8)

ΔH:3·162+0−1219=−733 kJ
The reaction is thermodynamically advantageous and is accompanied by heat emission.
In order for the substances to have reacted completely one needs to take 3 mole of CuO and 2 mole of V, resulting in formation of 2 mole of Cu and 1 mole of V₂O₃.

| Substance | CuO | Cu | V | V₂O₃ |
|---|---|---|---|---|
| Mass 1 mole, g | 80 | 64 | 50 | 100 |
| Density, g/cm³ | 6.45 | 8.96 | 5.96 | 4.87 |

Thicknesses are obtained using the following calculations

hCuO=(3·80)/6.45=37 nm

hV=(2·50)/5.96=17 nm

hCu+V₂O₃=(3·64)/8.96+100/4.87=21+21 nm=42 nm

Δh=57−42=15 nm(26%).
For full reaction one needs to have 37 nm of CuO film and 17 nm of V film. The reaction will result in shrinkage of the thickness at 26%.

CuO—Si

2CuO+Si=2Cu+SiO₂ (9)

ΔH:2·162+0−908=−584 kJ

The reaction is thermodynamically advantageous and is accompanied by heat emission.
In order for the substances to have reacted completely one needs to take 2 mole of CuO and 1 mole of Si, resulting in formation of 2 mole of Cu and 1 mole of SiO₂.

| Substance | CuO | Cu | Si | SiO₂ |
|---|---|---|---|---|
| Mass 1 mole, g | 80 | 64 | 28 | 60 |
| Density, g/cm³ | 6.45 | 8.96 | 2.33 | 2.65 |

For complete reaction one needs to use the following thicknesses of the films

hCuO=(2.80)/6.45=25 nm

hSi=(28)/2.33=12 nm

hCu+SiO₂=(2.64)/8.96+60/2.65=14+22=36 nm

Δh=47−36=11 nm(24%).

The resulting shrinkage of the film is 24%.

CuO—Cu

CuO+Cu=Cu₂O (10)

ΔH:162+0−173=−11 kJ
The Reaction is thermodynamically advantageous and is accompanied by heat emission.
In order for the substances to have reacted completely one needs to take 1 mole of CuO and 1 mole of Cu, resulting in formation of 1 mole of Cu₂O.

| Substance | CuO | Cu | Cu₂O |
|---|---|---|---|
| Mass 1 mole, g | 80 | 64 | 143 |
| Density, g/cm³ | 6.45 | 8.96 | 6.0 |

hCuO=(80)/6.45=12.5 nm

hCu=(64)/8.96=7.14 nm

hCu₂O=(143)/6.0+60/2.65=28.83 nm

Δh=12.5+7.14−28.83=−9.19 nm(−46%).
In this case thickness will increase at 46%.

CuO—H₂

CuO+H₂=Cu+H₂O (11)

ΔH:162+0−285=−123 kJ
The reaction is thermodynamically advantageous and is accompanied by heat emission.

| Substance | CuO | Cu |
|---|---|---|
| Mass 1 mole, g | 80 | 64 |
| Density, g/cm³ | 6.45 | 8.96 |

In calculations one can assume that densities of H₂ and H₂O are negligibly smaller than those of Cu and CuO and therefore thicknesses are given by

hCuO=(80)/6.45=12.5 nm

hCu=(64)/8.96=7.14 nm

Δh=12.5−7.14=5.36 nm(42.8%).
The thickness reduces to 42.8%.
In the case when Cu is used as a structured material with CuO on top of it (or vice versa), then reduction of Cu from the CuO oxide will result in formation of pure Cu layer with reduced thickness.
Hydrogen can be supplied into the reaction through the top metal as shown in FIG. 2. The resulting H₂O molecules can leave the cavity through the top metal too because the water will be in a vapor state. Finally, the cavity will be empty of any gas.
Reduction of Ag from its oxide can be used too.

Ag₂O—H₂

Ag₂O+H₂=2Ag+H₂O (12)

ΔH:31.1+0−285=−254 kJ
The reaction is thermodynamically advantageous and is accompanied by heat emission.
In order for the substances to have reacted completely one needs to take 1 mole of Ag₂O and 1 mole of H₂, resulting in formation of 2 moles of Ag and 1 mole of H₂O.

| Substance | Ag₂O | Ag |
|---|---|---|
| Mass 1 mole, g | 231.6 | 107.8 |
| Density, g/cm³ | 7.14 | 10.5 |

For full reaction, the thicknesses per square unit will be

hAg₂O=(231.6)/7.14=32.4 nm

hAg=(2·107.8)/10.5=20.53 nm

Δh=32.4−20.53=11.86 nm(36.6%).
Resulting shrinkage of the layer will be 36.6%.

Re₂O₇—H₂

Re₂O₇+7H₂=7H₂O+2Re (13)
In order for the substances to have reacted completely one needs to take 1 mole of Re₂O₇ and 7 moles of H₂, resulting in formation of 2 moles of Re and 7 moles of H₂O.
Taking into account the following data

| Substance | Re₂O₇ | Re |
|---|---|---|
| Mass 1 mole, g | 484.4 | 186.2 |
| Density, g/cm³ | 8.2 | 21 |

For full reaction, the thicknesses per square unit will be

hRe₂O₇=452.4/8.2=59 nm

hRe=(186·2)/21=18 nm

Δh=59−18=41 nm(69.9%).
The resulting shrinkage of the layer will be around 70%.
Reduction of Re from Re₂O₇ can be made at temperatures between 500 to 1200° C.
Some semiconductor materials can also be used as a density-changing material. These include

1) GeO₂—Al

3GeO₂+2Al=Al₂O₃+3Ge

2) SiO₂—Ti

SiO₂+Ti=TiO₂+Si

3) SiO₂—Al

3SiO₂+2Al=Al₂O₃+3Si

4) TiS₂

TiS₂+3O₂=TiO₂+2SO₂ The above-described methods are not limited to only horizontal gaps. Vertical gaps can also be fabricated. Also, combinations of horizontal and vertical gaps can be made as shown in FIG. 12.

The embodiments illustrated and discussed in this specification are intended only to teach those skilled in the art the best way known to the inventors to make and use the invention. In describing embodiments of the invention, specific terminology is employed for the sake of clarity. However, the invention is not intended to be limited to the specific terminology so selected. The above-described embodiments of the invention may be modified or varied, without departing from the invention, as appreciated by those skilled in the art in light of the above teachings. It is therefore to be understood that, within the scope of the claims and their equivalents, the invention may be practiced otherwise than as specifically described.

We claim:

1. A method of producing an electromechanical device, comprising:
forming a layer of density-changing material on a substructure; and
forming a support layer on at least a portion of said layer of density-changing material,
wherein said density-changing material has a first density during said forming said layer and a second density subsequent to said forming said support layer, said second density being greater than said first density such that said layer of density-changing material shrinks in at least one dimension to provide a gap between said layer of density changing material and at least one of said support layer and said substructure.

2. A method of producing an electromechanical device according to claim 1, wherein said density-changing material changes density due to a phase change in a structure of said density-changing material.

3. A method of producing an electromechanical device according to claim 1, wherein said density-changing material changes density due to sublimation.

4. A method of producing an electromechanical device according to claim 1, wherein said support layer is formed entirely over said layer of density-changing material such that said layer of density-changing material provides a membrane structure after it shrinks in said at least one dimension to provide a gap.

5. A method of producing an electromechanical device according to claim 4, wherein said support layer and said substructure provide an enclosure such that said gap is substantially a vacuum relative to a surrounding environment.

6. A method of producing an electromechanical device according to claim 1, wherein said support layer is formed over a portion of said layer of density-changing material leaving an end of said density-changing material uncovered such that said layer of density-changing material provides a cantilever structure after it shrinks in said at least one dimension to provide a gap.

7. A method of producing an electromechanical device according to claim 1, wherein said forming said layer of density-changing material comprises forming a first sub layer of a first material and a second sub layer of a second material, wherein said first and second materials chemically react with each other.

8. A method of producing an electromechanical device according to claim 7, wherein said forming said layer of density-changing material further comprises forming a sub layer of a buffer material between said first and second sub layers to regulate a speed of reaction of said first and second materials.

9. A method of producing an electromechanical device according to claim 7, further comprising transferring energy to said layer of density-changing material to initiate a chemical reaction between said first sub layer of said first material and said second sub layer of said second material to cause said layer of density-changing material to shrink in at least one dimension.

10. A method of producing an electromechanical device according to claim 9, wherein said transferring energy includes at least one of heating said layer of density-changing material, passing an electrical current through said layer of density-changing material, or directing electromagnetic radiation onto said layer of density-changing material.

11. A method of producing an electromechanical device according to claim 1, wherein said forming said layer of density-changing material comprises forming a plurality of sub layers of respective pluralities of materials, wherein at least two of said pluralities of materials chemically react with each other.

12. A method of producing an electromechanical device according to claim 1, wherein said gap is less than 1 μm such that said electromechanical device is a micro-electromechanical system.

13. A method of producing an electromechanical device according to claim 1, wherein said gap is less than 0.5 μm such that said electromechanical device is a nano-electromechanical system.

14. A method of producing an electromechanical device according to claim 1, wherein said gap is less than 1 μm and greater than 0.5 nm.

15. A method of producing an electromechanical device according to claim 1, wherein said gap is less than 0.5 μm and greater than 0.5 nm.

16. A method of producing an electromechanical device according to claim 1, further comprising forming a second layer of a second density-changing material on said support layer,
wherein said second density-changing material has a first density during said forming said second layer and a second density subsequent to said forming said second layer, said second density of said second layer being greater than said first density of said second layer such that said second layer of density-changing material shrinks in at least one dimension to provide a gap between said second layer of density changing material and at least one of said support layer and said first layer of density-changing material.

17. An electromechanical device produced according to claim 1.

18. A combined electronic and electromechanical device, comprising:
a substrate;
an electronic circuit formed on said substrate; and
an electromechanical system formed on said substrate to provide a combined electronic and electromechanical device on a common substrate,
wherein said electromechanical system comprises a structure that is free to move within a gap defined by said electromechanical system.

19. A combined electronic and electromechanical device according to claim 18, wherein said electronic circuit is a CMOS circuit.

20. A combined electronic and electromechanical device according to claim 18, wherein said structure of said electromechanical system that is free to move is a membrane.

21. A combined electronic and electromechanical device according to claim 20, wherein said electromechanical system comprises enclosing structures such that said gap is substantially a vacuum relative to a surrounding environment.

22. A combined electronic and electromechanical device according to claim 18, wherein said structure of said electromechanical system that is free to move is a cantilever.

23. A combined electronic and electromechanical device according to claim 18, wherein said gap is less than 1 μm such that said electromechanical system is a micro-electromechanical system.

24. A combined electronic and electromechanical device according claim 18, wherein said gap is less than 0.5 μm such that said electromechanical device is a nano-electromechanical system.

25. A combined electronic and electromechanical device according claim 18, wherein said gap is less than 1 μm and greater than 0.5 nm.

26. A combined electronic and electromechanical device according to claim 18, wherein said gap is less than 0.5 μm and greater than 0.5 nm.

27. An electromechanical system, comprising:
a substructure; and
a movable component attached to said substructure such that a gap is provided between said movable component and said substructure,
wherein said gap is less than about 500 nm.

28. An electromechanical system according to claim 27, wherein said movable component is a membrane.

29. An electromechanical system according to claim 28, wherein said electromechanical system comprises enclosing structures such that said gap is substantially a vacuum relative to a surrounding environment.

30. An electromechanical system according to claim 27, wherein said movable component is a cantilever.

31. An electromechanical system according to claim 27, wherein said gap is less than about 200 nm.

32. An electromechanical system according to claim 27, wherein said gap is less than about 100 nm and greater than about 0.5 nm.

33. An apparatus comprising an electromechanical system, said electromechanical system, comprising:
a substructure; ad
a movable component attached to said substructure such that a gap is provided between said movable component and said substructure,
wherein said gap is less than about 500 nm.

34. A method of producing a waveguide, comprising:
providing a substructure;
forming a layer of density-changing material on said substructure; and
forming an upper layer on at least a portion of said layer of density-changing material,
wherein said density-changing material has a first density during said forming said layer and a second density subsequent to said forming said upper layer, said second density being greater than said first density such that said layer of density-changing material shrinks in at least one dimension to provide a gap between said layer of density changing material and at least one of said upper layer and said substructure.

35. A device comprising a waveguide produced according to the method of claim 34.
